(19) United States
(12) Patent Application Publication
(10) Pub. No.: US 2025/0046775 A1
(43) Pub. Date: Feb. 6, 2025

(54) REMAPPING LAYERS FOR PHOTONIC INTERPOSERS

(71) Applicant: Lightmatter, Inc., Boston, MA (US)

(72) Inventors: Chian-min Richard Ho, Palo Alto, CA (US); Clifford Chao, Palo Alto, CA (US); Jessie Rosenberg, Bedford, MA (US); Anthony Kopa, Somerville, MA (US); Hamid Eslampour, San Jose, CA (US); Darius Bunandar, Boston, MA (US)

(73) Assignee: Lightmatter, Inc., Boston, MA (US)

(21) Appl. No.: 18/790,084

(22) Filed: Jul. 31, 2024

Related U.S. Application Data
(60) Provisional application No. 63/517,086, filed on Aug. 1, 2023.

(51) Int. Cl. H01L 25/16; H01L 23/00; H01L 23/498; H01L 23/64; H01L 25/065

(52) U.S. Cl. CPC H01L 25/167; H01L 23/49827; H01L 23/49838; H01L 23/647; H01L 24/08; H01L 25/0657; H01L 2224/08188; H01L 2224/08238

(57) ABSTRACT

Described herein is a packaging approach that employs a remapping layer to maintain compatibility to different types of electronic chips while allowing chip designers to standardize the layout of the electrical interface of a photonic interposer. A remapping layer remaps the electrical interface of an electronic chip to the electrical interface of a photonic interposer. Remapping layers may be implemented in various ways, including for example as monolithic electronic interposers and/or as individual remapping chips. In some embodiments, to reduce manufacturing costs, remapping layers may be implemented using passive electronics (without transistors). Because remapping layers are significantly less costly to manufacture than photonic interposers, shifting the need to provide ad hoc electrical interfaces from the photonic interposer to the remapping layer enhances the applicability of photonic interposers in computational, telecom and datacom settings.

### CROSS-REFERENCE TO RELATED APPLICATIONS

This application claims the benefit under 35 U.S.C. § 119 (e) of U.S. Provisional Application Ser. No. 63/517,086, filed on Aug. 1, 2023, under Attorney Docket No. L0858.70078US00 and entitled “BUMP REMAP/INDIRECTION INTERPOSER,” which is hereby incorporated herein by reference in its entirety.

### BACKGROUND

Photonic chips, also known as photonic integrated circuits (PICs), are devices that integrate multiple photonic functions (such as light manipulation and detection) on a single chip. These chips use photons, the fundamental particles of light, to perform operations that would traditionally be done by electronic circuits using electrons. Photonic chips can transmit data at speeds much faster than electronic chips, making them ideal for applications in high-speed internet and telecommunications. Photonic chips represent a significant advancement in the field of photonics and are poised to play a crucial role in the future of computing, communication, and various other technologies.

### BRIEF SUMMARY

Some embodiments relate to an electronic-photonic package, comprising: a photonic interposer photolithographically patterned with a plurality of photonic tiles optically coupled to one another to form a programmable photonic network, wherein each of the photonic tiles of the photonic interposer comprises an electrical interface; a first plurality of electronic chips, each electronic chip of the first plurality of electronic chips comprising an electrical interface different from the electrical interface of the photonic tiles; and a remapping layer bonded between the photonic interposer and the first plurality of electronic chips, wherein the remapping layer comprises a first electrical interface compatible with the electrical interface of the photonic interposer and a second electrical interface compatible with the electrical interface of the first plurality of electronic chips.

Some embodiments relate to an electronic-photonic package, comprising a photonic interposer photolithographically patterned with a plurality of photonic tiles optically coupled to one another to form a programmable photonic network, wherein each of the photonic tiles of the photonic interposer comprises an electrical interface; and a remapping layer bonded to the photonic interposer, wherein the remapping layer comprises a first electrical interface compatible with the electrical interface of the photonic interposer and a second electrical interface different from the first electrical interface.

Some embodiments relate to a method for manufacturing a package, comprising bonding a remapping layer comprising first and second electrical interfaces to a photonic interposer photolithographically patterned with a plurality of photonic tiles optically coupled to one another to form a programmable photonic network, wherein each of the photonic tiles of the photonic interposer comprises an electrical interface, wherein bonding the remapping layer to the photonic interposer comprises electrically connecting the electrical interface of the photonic interposer to the first electrical interface of the remapping layer; and bonding the remapping layer to a first plurality of electronic chips each comprising an electrical interface different from the electrical interface of the photonic tiles, wherein bonding the remapping layer to the first plurality of electronic chips comprises electrically connecting the electrical interface of the first plurality of electronic chips to the second electrical interface of the remapping layer.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A illustrates an example computing system based on a photonic interposer with nine photonic tiles arranged in three rows and three columns, in accordance with some embodiments.

FIG. 1B is a cross-sectional view of another example photonic interposer, in accordance with some embodiments.

FIG. 2A is a top view of a photonic tile, in accordance with some embodiments.

FIG. 2B is a top view of a photonic interposer including multiple photonic tiles of the type illustrated in FIG. 2A, in accordance with some embodiments.

FIG. 3A is a schematic diagram illustrating a photonic interposer and a plurality of electronic chips.

FIG. 3B is a schematic diagram illustrating a remapping layer disposed between a photonic interposer and a plurality of electronic chips, in accordance with some embodiments.

FIG. 3C is a schematic diagram illustrating a remapping layer disposed between a photonic interposer and a plurality of electronic chips including compute chips and high bandwidth memory chips, in accordance with some embodiments.

FIG. 4A is a cross-sectional side view illustrating a photonic interposer and a plurality of electronic chips.

FIG. 4B is a cross-sectional side view illustrating an electronic interposer disposed between a photonic interposer and a plurality of electronic chips, in accordance with some embodiments.

FIG. 4C is a cross-sectional side view illustrating an electronic interposer bonded between a photonic interposer and a plurality of electronic chips, in accordance with some embodiments.

FIG. 4D is a cross-sectional side view illustrating an electronic tile of an electronic interposer, in accordance with some embodiments.

FIG. 5 is a cross-sectional side view illustrating a plurality of remapping chips disposed between a photonic interposer and a plurality of electronic chips, in accordance with some embodiments.

FIG. 6A is a block diagram illustrating communication protocols that may be supported using various remapping schemes, in accordance with some embodiments.

FIG. 6B is another block diagram illustrating communication protocols that may be supported using various remapping schemes, in accordance with some embodiments.

### DETAILED DESCRIPTION

### I. Overview

Described herein are advanced chip packages that can adapt programmable photonic interposers to various types of electronic chips, including compute chips (e.g., processor chips or graphic processing unit chips), memory chips (e.g., single memory chips or high bandwidth memory chips), router chips, etc. Photonic interposers of the types described herein include substrates made of semiconductor materials that have been photolithographically patterned to define programmable photonic interconnects. The photonic interposers described herein can be manufactured using reticle stitching techniques. This approach enables fabrication of photonics using standard semiconductor foundries that require that the same photomask set (or at least one photomask) be used across an entire wafer. Using this approach, a photonic interposer may be patterned to have photonic tiles—tiles having the same layout, where each tile is the result of a reticle instantiation using step-and-repeat photolithography-based manufacturing.

Photonic interposers are designed to accommodate electronic chips and to enable the electronic chips to communicate with one another, in a programmable fashion, in the optical domain. The electronic chips can be bonded to the photonic interposer. For example, bumps or other types of electrical connections may connect a conductive pad formed on a surface of an electronic chip to a corresponding conductive pad formed on a surface of a photonic interposer. The bumps provide electrical connectivity between the chips or to other layers of a 3D-stack of chiplets or other interposers. In embodiments in which photonic interposers are divided into photonic tiles, each photonic tile may be bonded to one or more electronic chips. Such identical tiles may be sized to the maximum reticle size of the manufacturing process for the layer.

The inventors have recognized and appreciated that existing packaging solutions based on programmable photonic interposers present a limitation. Different types of electronic chips usually have different layouts for the electrical connections designed to link them to other chips. Electrical connections of the types described herein may be arranged, among other examples, as ball grid arrays (BGA), land grid arrays (LGA), though silicon vias (TSV), conductive bumps (e.g., solder), etc. The layout of a BGA, LGA or other types of connections refers to the specific arrangement and design of the connection points (solder balls for BGA or flat lands for LGA) on the outer surface of a chip. This layout determines how a chip interfaces with a printed circuit board (PCB) or interposer. The layout of a BGA or LGA on the surface of a chip is a critical aspect of the chip's design, affecting its electrical performance, thermal management, mechanical stability, and manufacturability. For BGAs, for example, balls are strategically placed to optimize electrical performance, thermal dissipation, and mechanical stability and the pitch (the distance between the centers of adjacent solder balls) typically varies based on the specific BGA type and application.

In the context of photonic interposer-based packages, the fact that different types of chips have different electrical interfaces poses a challenge. To allow a photonic interposer to support different types of electronic chips while maintaining interface compatibility, the electrical interface of the interposer should be designed ad hoc. However, designing the electrical interface of a photonic interposer ad hoc can increase manufacturing costs significantly, making photonic interposer-based packages less attractive.

Recognizing these limitations, the inventors have developed a packaging approach that employs a remapping layer to maintain compatibility to different types of electronic chips while allowing chip designers to standardize the layout of the electrical interface of a photonic interposer. A remapping layer remaps the electrical interface of an electronic chip to the electrical interface of a photonic interposer. Remapping layers may be implemented in various ways, including for example as monolithic electronic interposers and/or as individual remapping chips. In some embodiments, to reduce manufacturing costs, remapping layers may be implemented using passive electronics (without transistors). Because remapping layers are significantly less costly to manufacture than photonic interposers, shifting the need to provide ad hoc electrical interfaces from the photonic interposer to the remapping layer enhances the applicability of photonic interposers in computational, telecom and datacom settings.

Accordingly, some embodiments are directed to an electronic-photonic package comprising a photonic interposer, a first plurality of electronic chips and a remapping layer bonded between the photonic interposer and the first plurality of electronic chips. The photonic interposer may be photolithographically patterned with a plurality of photonic tiles optically coupled to one another to form a programmable photonic network. Each of the photonic tiles of the photonic interposer comprises an electrical interface. Each electronic chip of the first plurality of electronic chips comprises an electrical interface different from the electrical interface of the photonic tiles. The remapping layer comprises a first electrical interface compatible with the electrical interface of the photonic interposer and a second electrical interface compatible with the electrical interface of the first plurality of electronic chips.

In some embodiments, the photonic tiles are identical to one another. Each photonic tile may have an area that is less than 26 mm×33 mm.

In some embodiments, the remapping layer further comprises through silicon vias (TSV). The first electrical interface may be electrically coupled to the second electrical interface through the TSVs.

In some embodiments, the remapping layer comprises an electronic interposer patterned with a plurality of electronic tiles. Each electronic tile of the electronic interposer may map to a respective photonic tile of the photonic interposer. Alternatively, the remapping layer comprises a plurality of remapping chips, and each remapping chip maps to a respective photonic tile of the photonic interposer.

In some embodiments, the package may further comprise a second plurality of electronic chips, each electronic chip of the second plurality of electronic chips comprising an electrical interface (e.g., type “B”) different from the electrical interface of the photonic tiles (e.g., type “B”) and different from the electrical interface of the first plurality of electronic chips (e.g., type “AB”). The remapping layer may comprise a third electrical interface compatible with the electrical interface of the second plurality of electronic chips. The first plurality of electronic chips may comprise compute chips and the second plurality of electronic chips may comprise memory chips (e.g., HBM).

Further embodiments are directed to a method for manufacturing a package, comprising bonding a remapping layer to a photonic interposer and bonding the remapping layer to a first plurality of electronic chips each. The remapping layer may comprise first and second electrical interfaces. The photonic interposer may be photolithographically patterned with a plurality of photonic tiles optically coupled to one another to form a programmable photonic network. Each of the photonic tiles of the photonic interposer may comprise an electrical interface. Bonding the remapping layer to the photonic interposer may comprise electrically connecting the electrical interface of the photonic interposer to the first electrical interface of the remapping layer. The first plurality of electronic chips may each comprise an electrical interface different from the electrical interface of the photonic tiles. Bonding the remapping layer to the first plurality of electronic chips may comprise electrically connecting the electrical interface of the first plurality of electronic chips to the second electrical interface of the remapping layer.

In some embodiments, the remapping layer further comprises a third electrical interface, and the method further comprises bonding the remapping layer to a second plurality of electronic chips each comprising an electrical interface different from the electrical interface of the photonic tiles and different from the electrical interface of the first plurality of electronic chips. Bonding the remapping layer to the second plurality of electronic chips may comprise electrically connecting the electrical interface of the second plurality of electronic chips to the third electrical interface of the remapping layer.

### II. Photonic Interposers

The photonic interposers described herein are manufactured using reticle stitching techniques. This approach enables fabrication of photonic tiles using standard semiconductor foundries that require that the same photomask set (or at least one photomask) be used across an entire wafer. Designing photonic tiles in this way enables fabrication of many tiles on the same semiconductor wafer while leveraging standard, low-cost step-and-repeat manufacturing processes. Thus, in some embodiments, the tiles are photolithographically patterned instantiations (shots) of a common template tile that are stitched together in a 1D or a 2D arrangement. In some embodiments, the same template tile is used to pattern all the photonic tiles of a photonic interposer. Other embodiments involve two template tiles, so that each tile of an interposer is formed either as an instantiation of the first template tile or an instantiation of the second template tile. Tiles of different templates may alternate in a row-by-row fashion, for example, such that neighboring rows of tiles are of different types. In yet other embodiments, the same template photonic tile is used across the entire photonic interposers, but the tiles of adjacent rows are stamped as mirrored versions of each other. The area of a photonic tile may be defined by the size of the reticle in the manufacturing facility in which the photonic interposer is manufactured. For example, the area (in the xy-plane) of a photonic tile may be less than 30 mm×40 mm, less than 30 mm×35 mm, less than 30 mm×30 mm, less than 28 mm×38 mm, less than 28 mm×35 mm, less than 28 mm×30 mm or less than 26 mm×33 mm, though other dimensions are also possible). In one example, the area of a tile is 24.8 mm×32 mm.

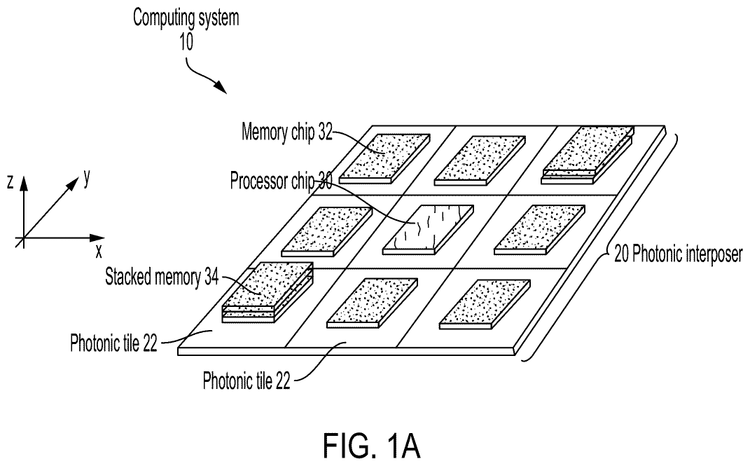

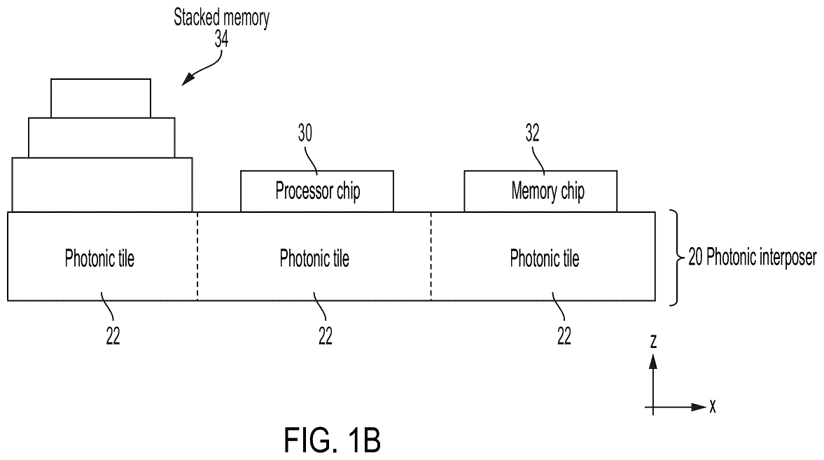

FIG. 1A illustrates an example computing system based on a photonic interposer with nine photonic tiles arranged in three rows and three columns, in accordance with one example. Computing system 10 includes a photonic interposer 20 patterned with nine photonic tiles 22. Photonic interposer 20 is implemented as a monolithic photonic integrated circuit (PIC), for example using silicon photonics.

Several electronic chips are mounted on the photonic interposer, which places the electronic chips in communication with each other photonically. In this example, photonic interposer 20 supports one processor chip (30) positioned in the middle of photonic interposer 20, and eight memory nodes surrounding the processor chip, although other computer architectures are possible. Some of the memory nodes include a single memory chip (see for example memory die 32). Other memory nodes include a stacked memory including multiple vertically stacked memory dies (see for example stacked memory 34), thus forming an HBM (high-bandwidth memory). The dies are stacked on top of portions of the PIC that define the tiles. A die communicates with the underlying tile electronically using electrical interfaces (e.g., through-silicon vias, copper pillars, micro-bumps, ball-grid arrays or other electrical interconnects).

FIG. 1B is a cross-sectional view of another example photonic interposer. As shown, photonic tiles 22 are formed photolithographically as part of interposer 20. Each photonic tile supports a corresponding electronic chip (although one tile may support more than one electronic chip and/or some photonic tiles may be unoccupied). Communication between the electronic chips occurs through the photonic tiles of photonic interposer 20.

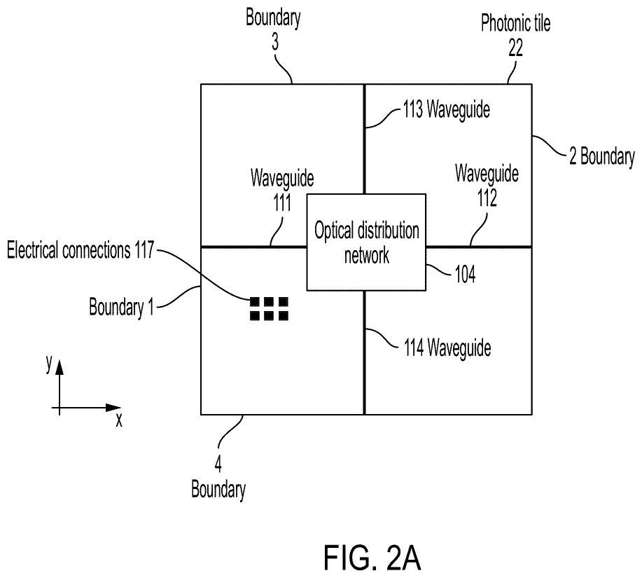

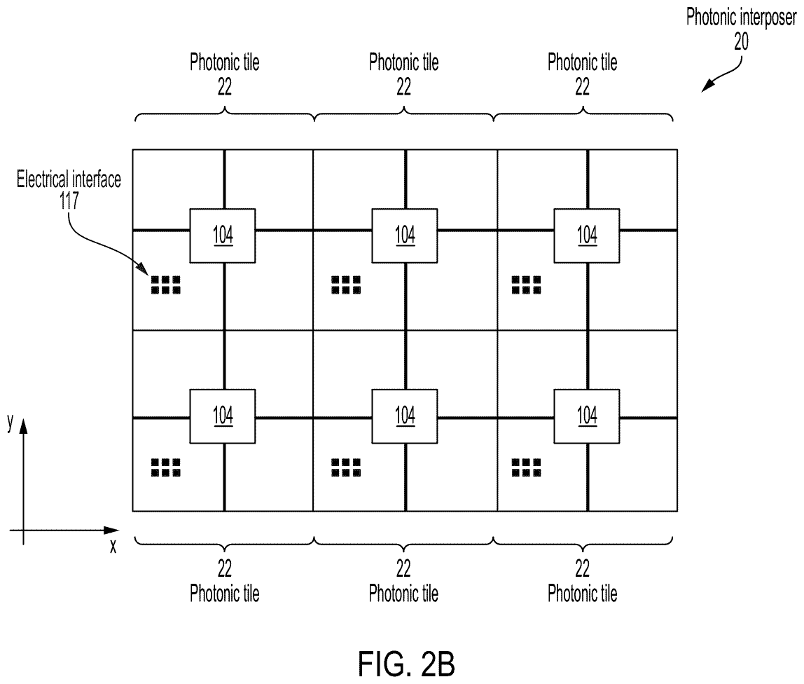

FIG. 2A illustrates an example tile 22. Tile 22 results from the instantiation of a reticle shot. In this example, tile 22 is shaped as a rectangle (though other shapes are also possible, such as squares or other polygons). As such, tile 22 is bounded by four boundaries (boundaries 1, 2, 3 and 4). Boundary 1 is opposite to boundary 2, and boundary 3 is opposite to boundary 4. Boundary 1 is adjacent to boundaries 3 and 4, and boundary 2 is also adjacent to boundaries 3 and 4. Tile 22 includes an optical distribution network 104 coupled to waveguides 111, 112, 113 and 114. Waveguide 111 optically couples optical distribution network 104 to boundary 1. As such, optical signals coupled from optical distribution network 104 to waveguide 111 can be transferred outside the tile by crossing boundary 1. Similarly, waveguide 112 optically couples optical distribution network 104 to boundary 2, waveguide 113 optically couples optical distribution network 104 to boundary 3 and waveguide 114 optically couples optical distribution network 104 to boundary 4. In some embodiments, the boundaries of a tile are defined based on a photolithography shot (e.g., the boundaries are defined by the boundaries of the photomask(s) used to fabricate the tile). In other embodiments, however, one photolithography shot may define more than one tile. For example, a photomask may be patterned with multiple side-by-side instances of a template tile. In some such embodiments, the boundaries of a tile are defined where adjacent instances of the template tile meet.

While the example of FIG. 2A illustrates waveguides coupling the optical distribution network to each of the boundaries, not all embodiments are arranged in this manner. In other embodiments, a tile 22 may include two of these four waveguides, such as waveguides 111 and 112, or waveguides 111 and 113. In yet other embodiments, a tile 22 may include three of these four waveguides, such as waveguides 111, 112 and 113. Optical distribution network 104 includes photonics components (e.g., programmable photonic switches) for routing optical signals inside and outside tile 22. Further, optical distribution network 104 may include transmitters (providing an electrical-optical interface with the electronic chip mounted on the tile) and receivers (providing an optical-electrical interface with the electronic chip mounted on the tile).

In some embodiments, a tile may include multiple layers of photonic waveguides. Similar to how multiple layers of conductive traces increase an electronic circuit's ability to route electric signals, multiple layers of waveguides increase a tile's ability to route optical signals. In one example, one layer includes silicon waveguides, and one or more additional layers include silicon nitride waveguides. The choice of material of each waveguide layer may be determined by the wavelength of light that will be routed by the waveguide. For example, silicon and silicon nitride layers may be used for routing infrared light in the telecommunication bands with wavelengths around 1.3 μm or 1.5 μm. In some examples, the multiple layers of waveguides may also include aluminum nitride waveguides that can be used to route visible light down to UV wavelengths or aluminum oxide waveguides that are used to route UV light. Each layer may be arranged in a configuration similar to that illustrated in FIG. 2A—with an optical distribution network that routes signals among the waveguides of the layer.

Tile 22 may further include one or more out-of-plane couplers (not shown in FIG. 2A). An out-of-plane coupler may be configured to emit light outside the xy-plane, for example in a direction parallel to the z-axis or at an angle relative to the z-axis. An out-of-plane coupler may be further configured to capture light incident from outside the xy-plane. In some embodiments, an out-of-plane coupler enables optical communication between tile 22 and a fiber disposed above the tile and/or below the tile. An out-of-plane coupler may be implemented using any suitable optical component, including for example optical gratings, lenses, and prisms. In some embodiments, the optical distribution network may be configured so that the same out-of-plane coupler enables optical communication in both directions—from optical distribution network 104 to a fiber and from the fiber to optical distribution network 104.

Optical distribution network 104 may selectively couple any components of tile 22 to any other components of tile 22. For example, optical distribution network 104 may enable passage of light between waveguide 111 and waveguide 112, and/or between waveguide 111 and waveguide 113, and/or between waveguide 113 and waveguide 114, etc. This may be achieved by equipping the optical distribution network with programmable optical switches (e.g., Mach Zehnder interferometers or microring resonators).

Tile 22 may further include electrical connections 117, which may be arranged to provide electrical access to a tile from the electronic chip mounted on that tile. For example, electrical connections 117 may be in the form of contact pads providing a landing surface for bonds, bumps, vias or other types of vertical chip-chip interconnects. Within the tile, electrical connections 117 may couple to the transmitters, receivers and switches of the optical distribution network, thus providing the electronic chip electrical access to those photonic components.

A photonic circuit may include multiple tiles connected together to collectively form an optical network. Photonic tiles may be coupled together using reticle stitching techniques, whereby a template tile is instantiated numerous times across a wafer in such a way so that, once instantiated, the waveguides of each tile are in optical alignment with the waveguides of the adjacent tiles (thereby forming an optical network). Photonic interposer 22 may be formed in this way.

FIG. 2B illustrates an example 2×3 photonic interposer including six photonic tiles 22. This photonic circuit is obtained by dicing a group of 2×3 tiles from a wafer. The tiles 22 are arranged so that waveguide 111 of an photonic tile is aligned with waveguide 112 of the photonic tile to the left of that photonic tile, waveguide 112 of an photonic tile is aligned with waveguide 111 of the photonic tile to the right of that photonic tile, waveguide 113 of an photonic tile is aligned with waveguide 114 of the photonic tile above that photonic tile and waveguide 114 of an photonic tile is aligned with waveguide 113 of the photonic tile below that photonic tile. As a result, the photonic tiles form an optical network. Optical distribution networks 104 may route optical signals anywhere inside or outside the network. Suppose, for example, that a processor chip is mounted to the tile positioned at the north-west corner of the photonic circuit and that a memory is mounted to the tile positioned at the south-east corner of the photonic circuit. A read operation may involve reconfiguring the optical distribution networks (e.g., by controlling its optical switches) to place the processor in optical communication with the memory.

As discussed above, waveguides of adjacent tiles are optically coupled to one another, thereby permitting passage of light from one tile to the next. In some embodiments, the end of the waveguides may be physically connected. In other embodiments, there may be a gap between the waveguides. In this example, each waveguide has an end that is located at a distance from the boundary. Thus, a gap is formed at the boundary region. Notwithstanding the gap, the waveguides of the adjacent tile are still optically coupled to each other. In this case, in fact, light emitted at the end of a waveguide reaches the end of the other waveguide by free space propagation.

### III. Remapping Layers

A remapping layer remaps the electrical interface of an electronic chip to the electrical interface of a photonic interposer. Remapping layers may be implemented in various ways, including for example as electronic interposers and/or as individual remapping chips. Use of remapping layers promotes compatibility to different types of electronic chips while allowing chip designers to standardize the layout of the electrical interface of a photonic interposer.

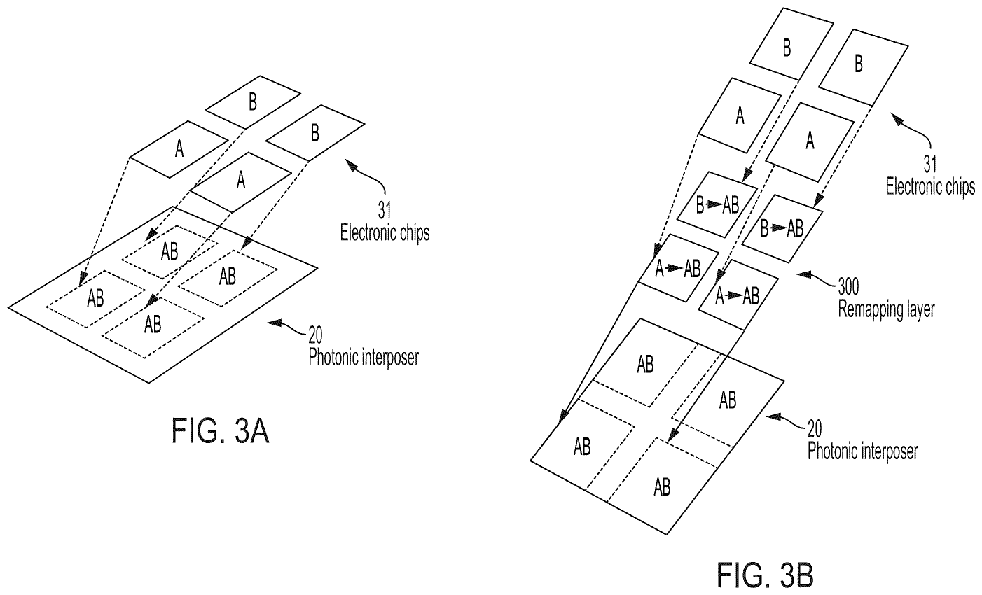

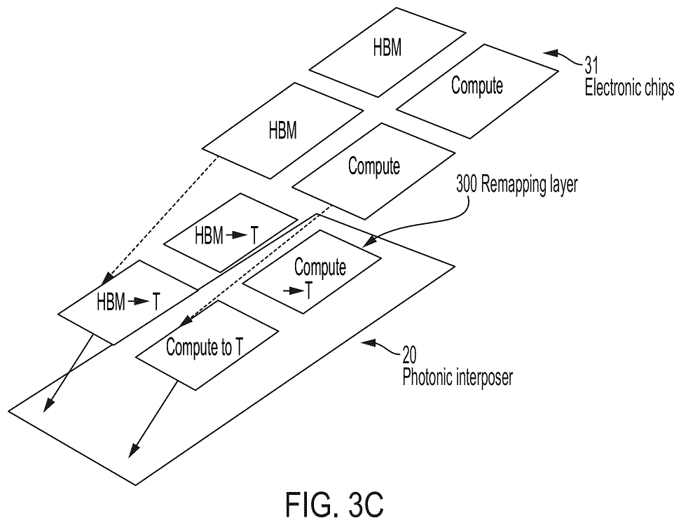

FIG. 3A is a schematic diagram illustrating a photonic interposer 20 and a plurality of electronic chips 31. This figure illustrates that the electrical interfaces of the electronic chips are generally incompatible with the electrical interface of photonic interposer 20. In this example, two electronic chips have electrical interfaces of the type “A” and the other two electronic chips have electrical interfaces of the type “B.” Electrical interfaces A and B differ from one another in that they have different layouts. Further, the tiles of photonic interposer 20 have electrical interfaces of the type “AB,” which is incompatible with either electrical interface A or B.

A remapping layer of the types described herein can be used to render the electrical interfaces compatible. FIG. 3B is a schematic diagram illustrating a remapping layer 300 disposed between a photonic interposer 20 and a plurality of electronic chips 31, in accordance with some embodiments. The remapping layer 300 includes remapping tiles that remap the electrical interface of the interposer to the electrical interfaces of the electronic chips. The remapping tiles of the type “A→AB” remap electrical interface A to electrical interface AB, thus rendering the electronic chips of the type A comparable with the interposer. The remapping tiles of the type “B→AB” remap electrical interface B to electrical interface AB, thus rendering the electronic chips of the type B comparable with the interposer. One specific example is shown in FIG. 3C. Here, a remapping layer 300 is disposed between a photonic interposer and a plurality of electronic chips including compute chips (“compute”) and high bandwidth memory chips (“HBM”). The remapping tiles of the type “Compute→T” remap electrical interface of the compute chips to the interposer, while the remapping tiles of the type “HBM→T” remap electrical interface of the high bandwidth memory chips to the interposer. As such, photonic interposer 20 can support communication between compute chips and high bandwidth memory chips in the optical domain despite having incompatible electrical interfaces.

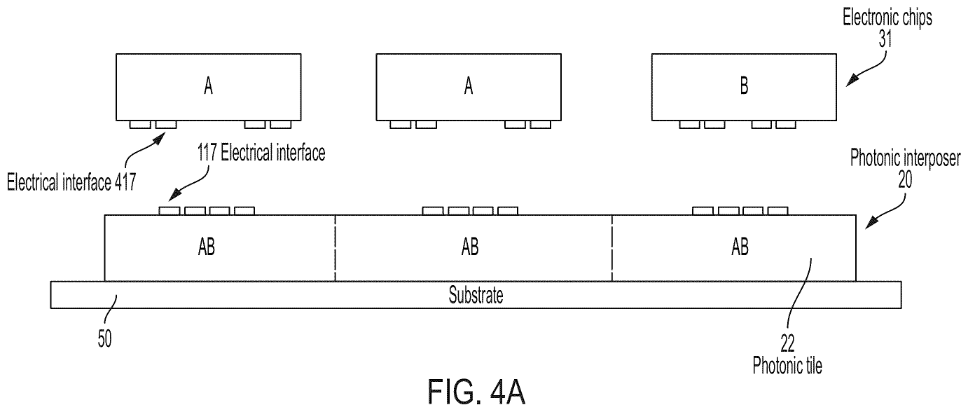

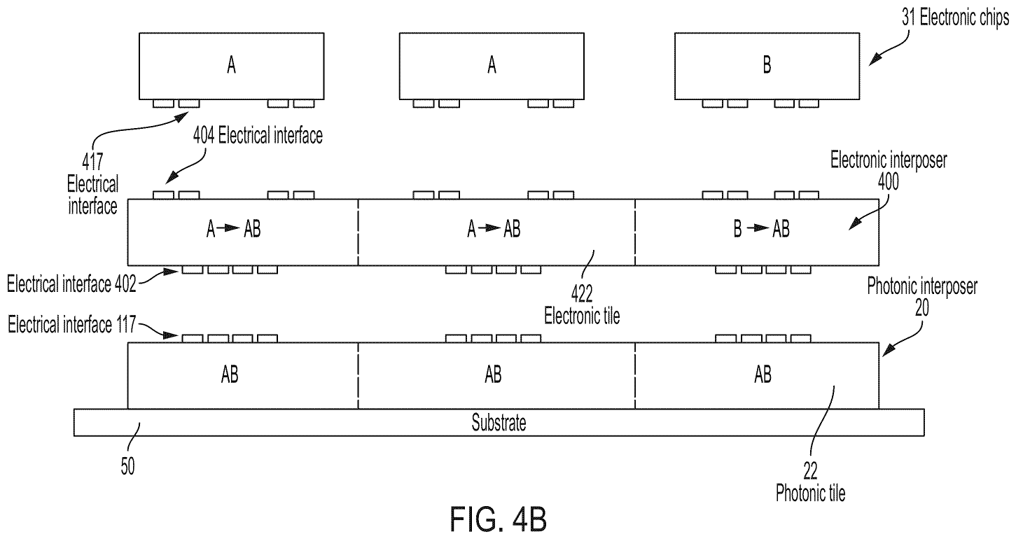

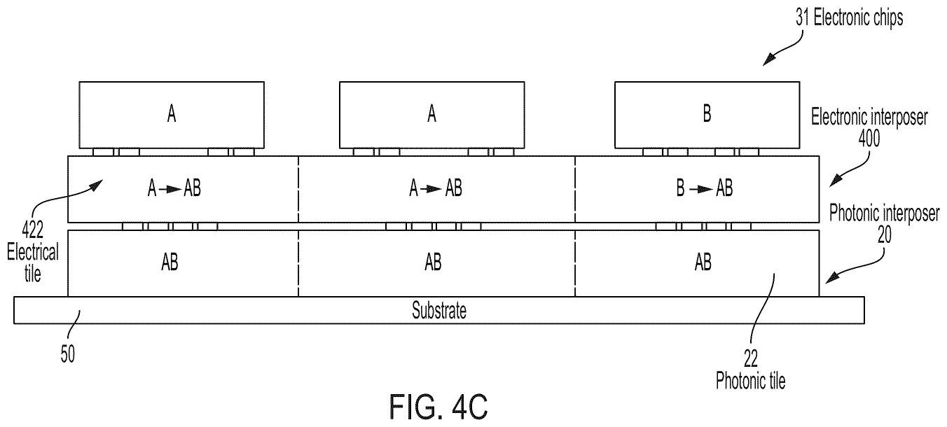

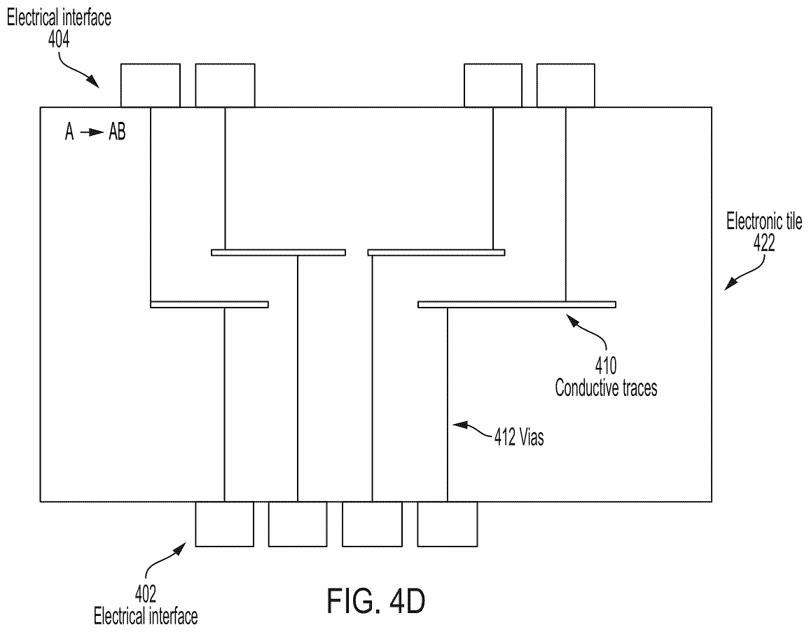

FIG. 4A is a cross-sectional side view illustrating a photonic interposer and a plurality of electronic chips, in the absence of a remapping layer. The package of FIG. 4B further includes a remapping layer disposed between the photonic interposer and the plurality of electronic chips. Photonic interposer 20 is arranged with multiple photonic tiles, as described above in connection with FIG. 2B.

Referring first to FIG. 4A, photonic interposer 20 is disposed on a substrate 50, which may be implemented as a PCB, an organic substrate, a carrier, a socket or any other suitable type of support. In this example, the photonic tiles 22 of photonic interposer 20 are identical to one another (having been fabricated using reticle stitching techniques using a single template), and are of the type “AB.” Each tile includes an electrical interface 117, which may include a certain layout of conductive pads, balls, bumps or other types of electrical connections.

Two of the electronic chips are of the same type (“A”) and one electronic chip is of another type (“B”). As such, the electrical interfaces (417) of the electronic chips of type A have the same layout, but have a different layout relative to the electrical interface of the chip of type B. In some embodiments, the electronic chips of type A may represent memory chips while the electronic chips of type B may represent compute chips. As can be appreciated from FIG. 4A, neither the electrical interfaces of the electronic chips of type A nor the electrical interface of the electronic chip of type B are compatible with the electrical interfaces of photonic interposer 20.

Referring now to FIG. 4B, a remapping layer in the form of an electronic interposer 400 is disposed between photonic interposer 20 and electronic chips 31. Electronic interposer 400 includes electrical interfaces 402 on the bottom side and electrical interfaces 404 on the top side. Electronic interposer 400 includes two types of tiles. The tiles of type “A→AB” remap the electrical interfaces of the electronic chips of type A to the electrical interfaces of the underlying photonic tiles. The tile of type “B→AB” remaps the electrical interface of the electronic chip of type B to the electrical interface of the underlying photonic tile. As such, electronic interposer 400 renders photonic interposer 20 electrically compatible to electronic chips 31.

In the depiction of FIG. 4C, electronic interposer 400 has been bonded between photonic interposer 20 and electronic chips 31. This arrangement may be obtained by bonding the electronic interposer to the photonic interposer and by bonding the electronic interposer to the electronic chips. The bonding steps may be performed in either order.

The tiles of the electronic interposer (422) may be patterned in a way similar to how photonic tiles 22 are patterned, using reticle stitching techniques. In some embodiments, all the tiles of the electronic chips are identical to one another. In other embodiments, the tiles are of different types (as in the examples of FIGS. 4B-4C). This may be obtained by adopting reticle stitching techniques using different reticle templates (one reticle template for each type of tile).

FIG. 4D is a cross-sectional side view illustrating an electronic tile of an electronic interposer in further detail, in accordance with some embodiments. FIG. 4D illustrates how electrical interface 402 is remapped to electrical interface 404 using a combination of conductive traces 410 and vias 412. Vias 412 may be through silicon vias (TSV) in some embodiments. Vias 412 couple the conductive traces to the electrical interfaces.

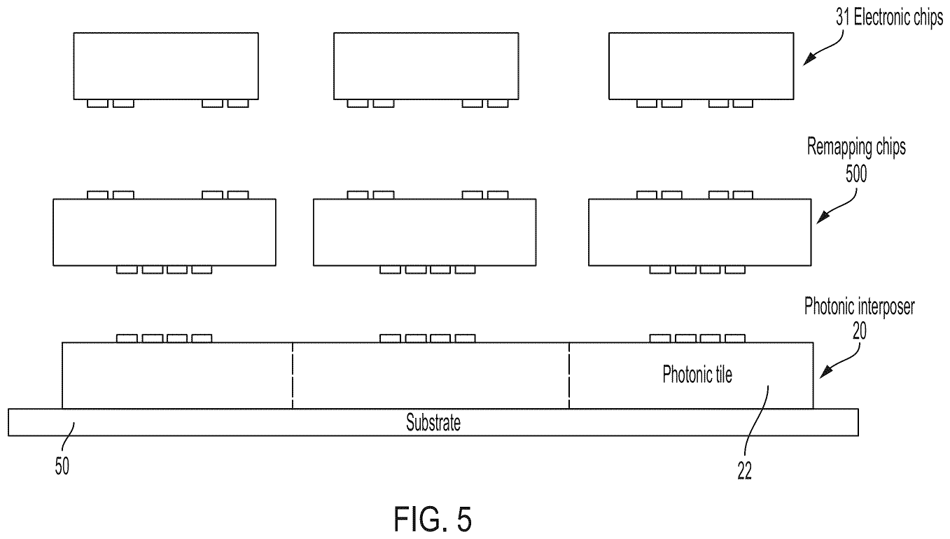

In the examples of FIGS. 4B-4C, the remapping layer is implemented using a monolithic electronic interposer. In other embodiments, however, a remapping layer may be implemented using individual chips (referred to herein as “remapping chips”). An example of this implementation is illustrated in FIG. 5. The implementation of FIG. 5 is similar to the implementation of FIG. 4B, but electronic interposer 400 has been replaced by remapping chips 500. Each remapping chip maps to a photonic tile 22 in the same way as each tile of electronic interposer 400 maps to a photonic tile 22.

In the examples described in connection with FIGS. 4B-4D and FIG. 5, there is a 1-to-1correspondence between photonic tiles and electronic chips. Each electronic chip has a dedicated photonic tile. In other embodiments, however, there may be more than one electronic chip per photonic tile, provided that the remapping layer provides remapping between the electrical interface of the shared photonic tile and the electrical interfaces of the electronic chips.

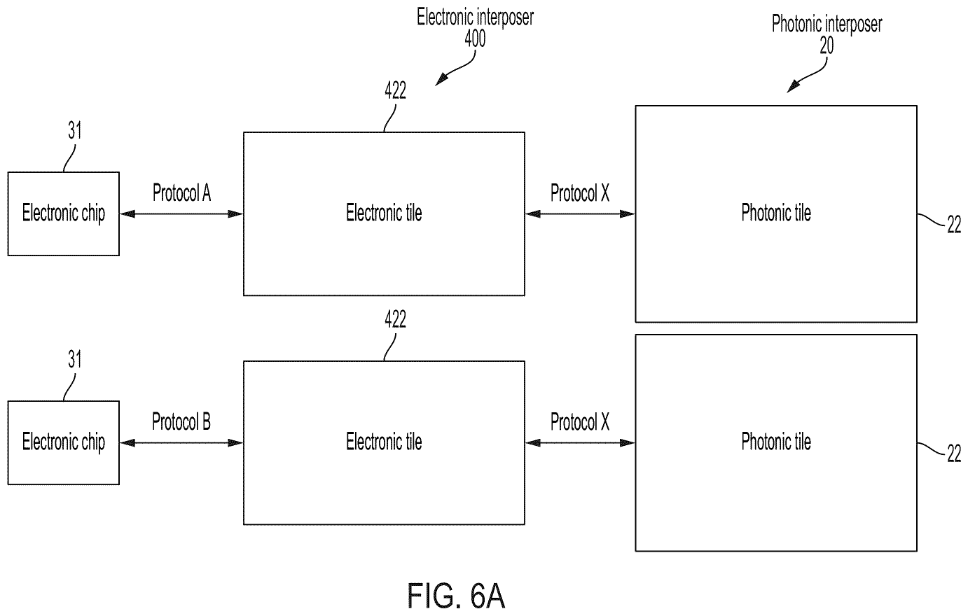

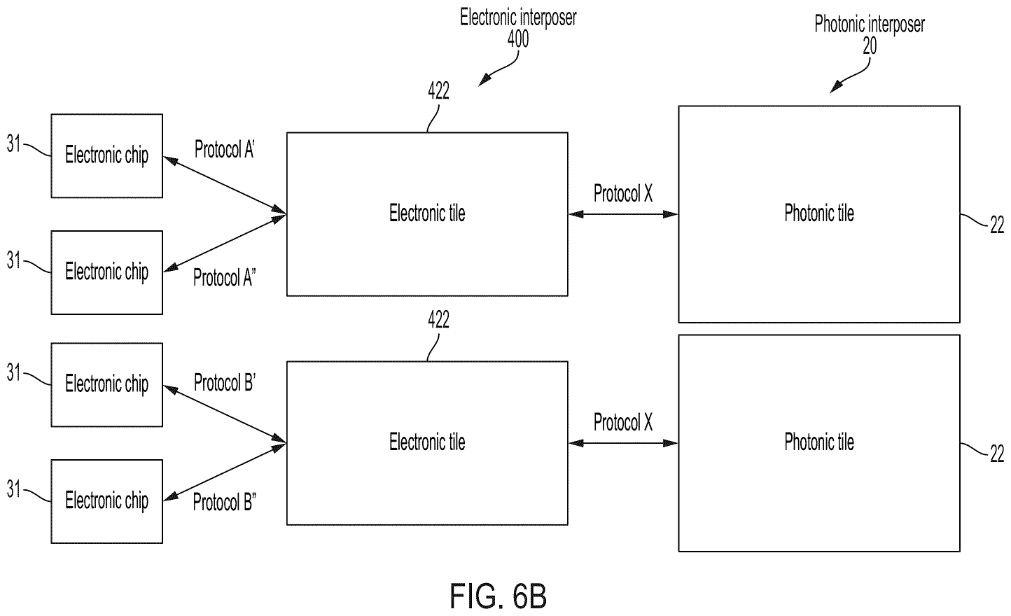

In addition to physically remapping the electrical interfaces of the electronic chips to the electrical interfaces of a photonic interposer, in some embodiments a remapping layer may perform protocol conversion. This is illustrated in the block diagrams of FIGS. 6A-6B. In the example of FIG. 6A, there is a 1-to-1 correspondence between photonic tiles and electronic chips, while in the example of FIG. 6B, each photonic tile is associated with a pair of electronic chips. In either configuration, the electronic tiles 422 of the remapping layer are configured to convert the communication protocol in place between the electronic interposer and the photonic interposer (protocol X) to the communication protocol in place between the electronic interposer and the electronic chips (either protocol A or protocol B in FIG. 6A, or any one of protocols A′, A″, B′ and B″ in FIG. 6B). For example, the communication protocol in place between the electronic interposer and the photonic interposer may be BoW (Bunch of Wires) and the communication protocol in place between the electronic interposer and the electronic chips may be UCle (Universal Chiplet Interconnect Express). In some embodiments, some rudimentary computing (such as averaging) may be performed by the remapping layer before the data is converted to the appropriate protocol.

### IV. Definitions

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described.

In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. An electronic-photonic package, comprising:
a photonic interposer photolithographically patterned with a plurality of photonic tiles optically coupled to one another to form a programmable photonic network, wherein each of the photonic tiles of the photonic interposer comprises an electrical interface;
a first plurality of electronic chips, each electronic chip of the first plurality of electronic chips comprising an electrical interface different from the electrical interface of the photonic tiles; and
a remapping layer bonded between the photonic interposer and the first plurality of electronic chips, wherein the remapping layer comprises a first electrical interface compatible with the electrical interface of the photonic interposer and a second electrical interface compatible with the electrical interface of the first plurality of electronic chips.

2. The electronic-photonic package of claim 1, wherein the photonic tiles are identical to one another.

3. The electronic-photonic package of claim 2, wherein each photonic tile has an area that is less than 26 mm×33 mm.

4. The electronic-photonic package of claim 1, wherein the remapping layer comprises through silicon vias (TSVs), wherein the first electrical interface is electrically coupled to the second electrical interface through the TSVs.

5. The electronic-photonic package of claim 1, wherein the remapping layer comprises an electronic interposer patterned with a plurality of electronic tiles, wherein each electronic tile of the electronic interposer maps to a respective photonic tile of the photonic interposer.

6. The electronic-photonic package of claim 1, further comprising a second plurality of electronic chips, each electronic chip of the second plurality of electronic chips comprising an electrical interface different from the electrical interface of the photonic tiles and different from the electrical interface of the first plurality of electronic chips, wherein:
the remapping layer comprises a third electrical interface compatible with the electrical interface of the second plurality of electronic chips.

7. The electronic-photonic package of claim 6, wherein the first plurality of electronic chips comprises compute chips and the second plurality of electronic chips comprises memory chips.

8. The electronic-photonic package of claim 7, wherein the second plurality of electronic chips comprises a bandwidth memory (HBM) chips.

9. The electronic-photonic package of claim 1, wherein the remapping layer comprises a plurality of remapping chips, wherein each remapping chip maps to a respective photonic tile of the photonic interposer.

10. The electronic-photonic package of claim 1, wherein the remapping layer is configured to convert a communication protocol associated with the first electrical interface to a communication protocol associated with the second electrical interface.

11. An electronic-photonic package, comprising:
a photonic interposer photolithographically patterned with a plurality of photonic tiles optically coupled to one another to form a programmable photonic network, wherein each of the photonic tiles of the photonic interposer comprises an electrical interface; and
a remapping layer bonded to the photonic interposer, wherein the remapping layer comprises a first electrical interface compatible with the electrical interface of the photonic interposer and a second electrical interface different from the first electrical interface.

12. The electronic-photonic package of claim 11, wherein the photonic tiles are identical to one another.

13. The electronic-photonic package of claim 12, wherein each photonic tile has an area that is less than 26 mm×33 mm.

14. The electronic-photonic package of claim 11, wherein the remapping layer comprises an electronic interposer patterned with a plurality of electronic tiles, wherein each electronic tile of the electronic interposer maps to a respective photonic tile of the photonic interposer.

15. The electronic-photonic package of claim 11, wherein the remapping layer comprises a plurality of remapping chips, wherein each remapping chip maps to a respective photonic tile of the photonic interposer.

16. A method for manufacturing a package, comprising:
bonding a remapping layer comprising first and second electrical interfaces to a photonic interposer photolithographically patterned with a plurality of photonic tiles optically coupled to one another to form a programmable photonic network, wherein each of the photonic tiles of the photonic interposer comprises an electrical interface, wherein bonding the remapping layer to the photonic interposer comprises electrically connecting the electrical interface of the photonic interposer to the first electrical interface of the remapping layer; and
bonding the remapping layer to a first plurality of electronic chips each comprising an electrical interface different from the electrical interface of the photonic tiles, wherein bonding the remapping layer to the first plurality of electronic chips comprises electrically connecting the electrical interface of the first plurality of electronic chips to the second electrical interface of the remapping layer.

17. The method of claim 16, wherein the remapping layer further comprises a third electrical interface, wherein the method further comprises:
bonding the remapping layer to a second plurality of electronic chips each comprising an electrical interface different from the electrical interface of the photonic tiles and different from the electrical interface of the first plurality of electronic chips, wherein bonding the remapping layer to the second plurality of electronic chips comprises electrically connecting the electrical interface of the second plurality of electronic chips to the third electrical interface of the remapping layer.

18. The method of claim 17, wherein the first plurality of electronic chips comprises compute chips and the second plurality of electronic chips comprises memory chips.

19. The method of claim 16, wherein:
bonding the remapping layer to the photonic interposer comprises bonding an electronic interposer having a plurality of electronic tiles to the photonic interposer so that each electronic tile of the electronic interposer maps to a respective photonic tile of the photonic interposer, and
bonding the remapping layer to the first plurality of electronic chips comprises bonding the electronic interposer to the first plurality of electronic chips so that each electronic tile of the electronic interposer further maps to a respective electronic chip of the first plurality of electronic chips.

20. The method of claim 16, wherein:
bonding the remapping layer to the photonic interposer comprises bonding a plurality of remapping chips to the photonic interposer so that each remapping chip maps to a respective photonic tile of the photonic interposer, and
bonding the remapping layer to the first plurality of electronic chips comprises bonding the plurality of remapping chips to the first plurality of electronic chips so that each remapping chip further maps to a respective electronic chip of the first plurality of electronic chips.
